(19) United States
(12) Patent Application Publication
(10) Pub. No.: US 2023/0411317 A1
(43) Pub. Date: Dec. 21, 2023

(54) CHIP PACKAGE

(71) Applicant: WALTON ADVANCED ENGINEERING, INC., KAOHSIUNG (TW)

(72) Inventors: HONG-CHI YU, KAOHSIUNG (TW); CHUN-JUNG LIN, KAOHSIUNG (TW); RUEI-TING GU, KAOHSIUNG (TW)

(21) Appl. No.: 18/207,658

(22) Filed: Jun. 8, 2023

(30) Foreign Application Priority Data
Jun. 9, 2022 (TW) 111121398

(51) Int. Cl. H01L 23/00

(52) U.S. Cl. CPC H01L 24/02; H01L 2224/13021; H01L 24/05; H01L 24/03; H01L 24/48; H01L 2224/0231; H01L 2224/0239; H01L 2924/01029; H01L 2924/01047; H01L 2224/02331; H01L 2224/0343; H01L 2224/0384; H01L 2224/05548; H01L 2224/05567; H01L 2224/0579; H01L 2224/05839; H01L 2224/05847; H01L 2224/05008; H01L 2224/05083; H01L 2224/0529; H01L 2224/05339; H01L 2224/05347; H01L 2224/05562; H01L 2224/05573; H01L 2224/48091; H01L 2224/48105; H01L 2924/01028; H01L 2924/01079; H01L 2924/01046; H01L 24/13

(57) ABSTRACT

A chip package which includes a chip, at least one first dielectric layer, at least one second dielectric layer, at least one conductive circuit, and at least one third dielectric layer is provide. The conductive circuit is formed by highly concentrated silver paste or copper paste filled in at least one first groove of the first dielectric layer and at least one second groove of the second dielectric layer while at least one die pad of the chip is electrically connected with the conductive circuit for improving electrical conduction efficiency of the conductive circuit. Moreover, at least one die-pad bump is formed in the first groove, arranged at and electrically connected with a surface of the die pad for protecting of the die pad.

### CROSS-REFERENCE TO RELATED APPLICATIONS

This non-provisional application claims priority under 35 U.S.C. § 119(a) on Patent Application No(s). 111121398 filed in Taiwan, R.O.C. on Jun. 9, 2022, the entire contents of which are hereby incorporated by reference.

### BACKGROUND OF THE INVENTION

The present invention relates to a chip package, especially to a chip package with higher conductive efficiency and better yield rate.

Along with fast development of semiconductor techniques, conductive efficiency and yield rate of convention chip package products are unable to meet manufacturers' requirements or consumers' needs and this decreases consumer's trust on the conventional chip package products. Thus there is room for improvement and there is a need to provide a novel chip package

### SUMMARY OF THE INVENTION

Therefore, it is a primary object of the present invention to provide a chip package which includes a chip, at least one first dielectric layer, at least one second dielectric layer, at least one conductive circuit, and at least one third dielectric layer. The conductive circuit is formed by highly concentrated silver paste or copper paste filled in at least one first groove of the first dielectric layer and at least one second groove of the second dielectric layer while at least one die pad of the chip is electrically connected with the conductive circuit for improving electrical conduction efficiency of the conductive circuit. Moreover, at least one die-pad bump is formed in the first groove and electrically connected with and arranged at a surface of the die pad for protecting the die pad and improving yield rate of products. Thereby a problem of reduced reliability of conventional chip package can be solved effectively.

In order to achieve the above object, a chip package according to the present invention includes a chip, at least one first dielectric layer, at least one second dielectric layer, at least one conductive circuit, and at least one third dielectric layer. The chip has a surface provided with at least one die pad and at least one chip protective layer thereover. The chip is formed by cutting of a wafer. The first dielectric layer is covering a surface of the chip protection layer of the chip and provided with at least one first groove by which the die pad is exposed. The second dielectric layer is covering a surface of the first dielectric layer and is provided with at least one second groove which is communicating with the first groove of the first dielectric layer. The conductive circuit is formed by highly concentrated silver paste or copper paste filled in the first groove and the second groove for allowing the die pad to be electrically connected with the conductive circuit. The third dielectric layer is covering both a surface of the second dielectric layer and a surface of the conductive circuit and provided with at least one opening by which the conductive circuit is exposed. At least one bonding pad is formed on the conductive circuit at a position corresponding to the opening for electrical connection to the outside.

In order to achieve the above object, a chip package according to the present invention includes a chip, at least one first dielectric layer, at least one a die-pad bump, at least one second dielectric layer, at least one conductive circuit, and at least one third dielectric layer. The chip has a surface provided with at least one die pad and at least one chip protective layer thereover. The chip is formed by cutting of a wafer. The first dielectric layer is covering a surface of the chip protection layer of the chip and provided with at least one first groove by which the die pad is exposed. The die-pad bump is formed in the first groove and electrically connected with and disposed over a surface of the die pad. The second dielectric layer is covering a surface of the first dielectric layer and is provided with at least one second groove which is communicating with the first groove of the first dielectric layer. The conductive circuit is formed by highly concentrated silver paste or copper paste filled in the second groove for allowing the die-pad bump to be electrically connected with the conductive circuit. The third dielectric layer is covering both a surface of the second dielectric layer and a surface of the conductive circuit and provided with at least one opening by which the conductive circuit is exposed. At least one bonding pad is formed on the conductive circuit at a position corresponding to the opening for electrical connection to external components.

### BRIEF DESCRIPTION OF THE DRAWINGS

FIG. 1 is a side view of a section of a first embodiment according to the present invention;

FIG. 2 is a side view of a section of a chip of an embodiment according to the present invention;

FIG. 3 is a side view of a section of the embodiment in FIG. 2 in which a first dielectric layer is disposed over the chip according to the present invention;

FIG. 4 is a side view of a section of the embodiment in FIG. 3 in which a second dielectric layer is disposed over the first dielectric layer according to the present invention;

FIG. 5 is a side view of a section of the embodiment in FIG. 4 in which highly concentrated silver paste or copper paste is filled into a first groove and a second groove according to the present invention;

FIG. 6 is a side view of a section of the embodiment in FIG. 5 in which the highly concentrated silver paste or copper paste at higher level than a surface of the second dielectric layer is ground to expose the surface of the second dielectric layer according to the present invention;

FIG. 7 is a side view of a section of the embodiment in FIG. 6 in which a third dielectric layer is arranged over a conductive circuit according to the present invention;

FIG. 8 is a side view of a section of a plurality of chip packages of a first embodiment located on a wafer according to the present invention;

FIG. 9 is a side view of a section of an embodiment of a chip package electrically connected with an electronic component by wire bonding according to the present invention;

FIG. 10 is a side view of a section of a second embodiment according to the present invention;

FIG. 11 is a side view of a section of the embodiment in FIG. 6 in which a conductive bump is disposed over a conductive circuit according to the present invention;

FIG. 12 is a side view of a section of the embodiment in FIG. 11 in which a first protective layer is disposed over the conductive bump according to the present invention;

FIG. 13 is a side view of a section of the embodiment in FIG. 12 in which a second protective layer is disposed over the first protective layer according to the present invention;

FIG. 14 is a side view of a section of the embodiment in FIG. 13 in which a third dielectric layer is disposed over the second protective layer according to the present invention;

FIG. 15 is a side view of a section of a plurality of chip packages of a second embodiment located on a wafer according to the present invention;

FIG. 16 is a side view of a section of a third embodiment according to the present invention;

FIG. 17 is a side view of a section of the embodiment in FIG. 2 in which a die-pad bump is disposed over a die pad according to the present invention;

FIG. 18 is a side view of a section of the embodiment in FIG. 17 in which a second dielectric layer is disposed over a first dielectric layer according to the present invention;

FIG. 19 is a side view of a section of the embodiment in FIG. 18 in which highly concentrated silver paste or copper paste is filled in a first groove and a second groove according to the present invention;

FIG. 20 is a side view of a section of the embodiment in FIG. 19 in which highly concentrated silver paste or copper paste over a surface of a second dielectric layer is ground and the surface of the second dielectric layer is exposed according to the present invention;

FIG. 21 is a side view of a section of the embodiment in FIG. 20 in which a third dielectric layer is arranged over a conductive circuit according to the present invention;

FIG. 22 is a side view of a section of a plurality of chip packages of a third embodiment located on a wafer according to the present invention;

FIG. 23 is a side view of a section of a fourth embodiment according to the present invention;

FIG. 24 is a side view of a section of the embodiment in FIG. 23 in which a conductive bump is disposed over a conductive circuit according to the present invention;

FIG. 25 is a side view of a section of the embodiment in FIG. 24 in which a first protective layer is disposed over the conductive bump according to the present invention;

FIG. 26 is a side view of a section of the embodiment in FIG. 25 in which a second protective layer is disposed over the first protective layer according to the present invention;

FIG. 27 is a side view of a section of the embodiment in FIG. 26 in which a third dielectric layer is disposed over the second protective layer according to the present invention;

FIG. 28 is a side view of a section of a plurality of chip packages of a fourth embodiment located on a wafer according to the present invention.

### DETAILED DESCRIPTION OF THE PROFFERED EMBODIMENT

In order to learn structure and technical features of the present invention, please refer to the following descriptions and related figures which are only used to explain relationship and functions of respective components of the present invention and sizes of the respective components are not drawn to real scale, and not intended to limit the scope of the present invention.

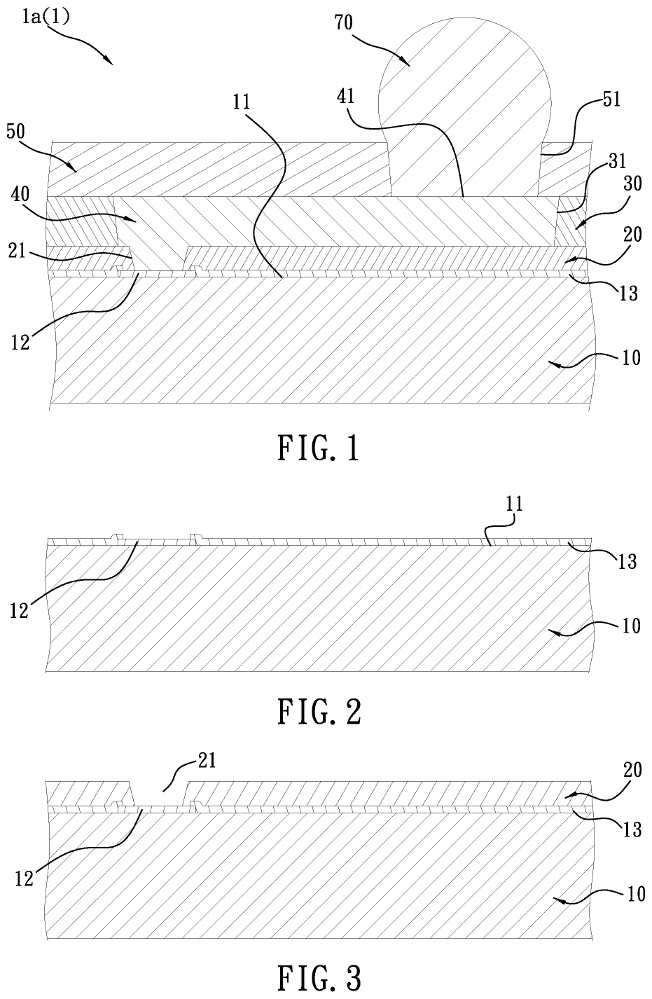

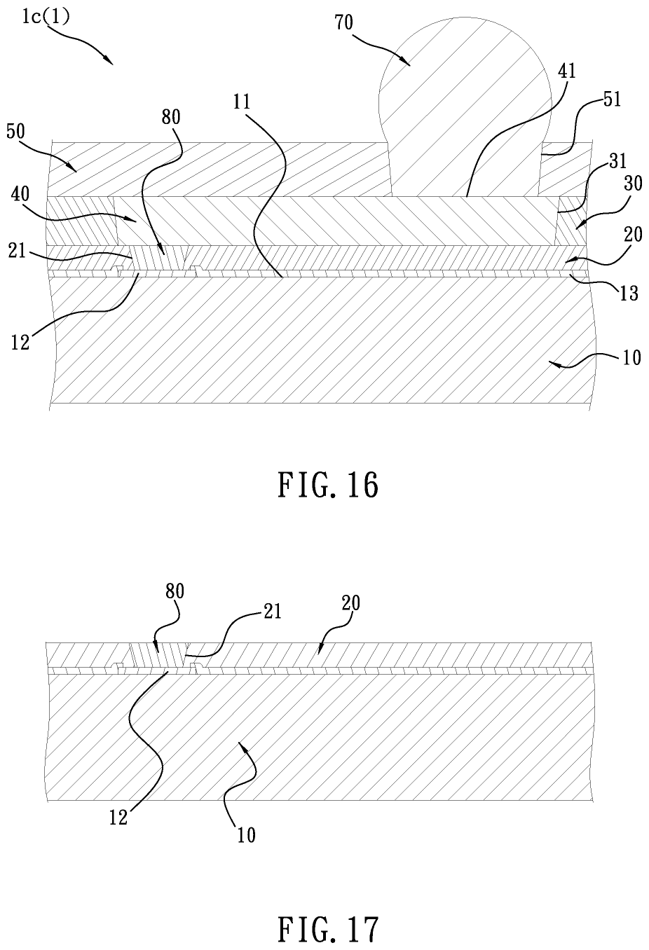

Refer to FIG. 1, FIG. 10, FIG. 16, and FIG. 23, a chip package 1 according to the present invention includes a chip 10, at least one first dielectric layer 20, at least one second dielectric layer 30, at least one conductive circuit 40, and at least one third dielectric layer 50.

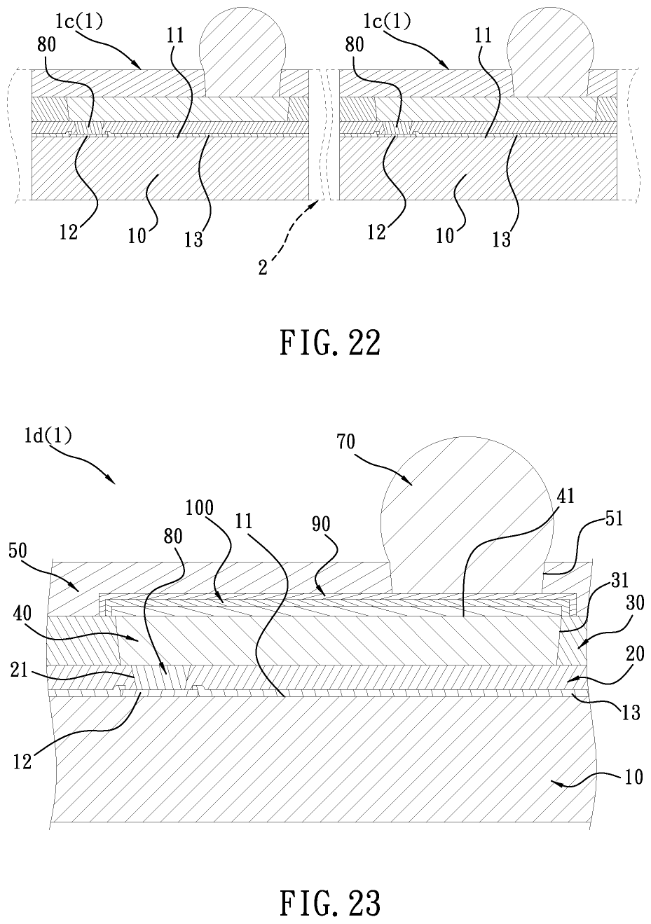

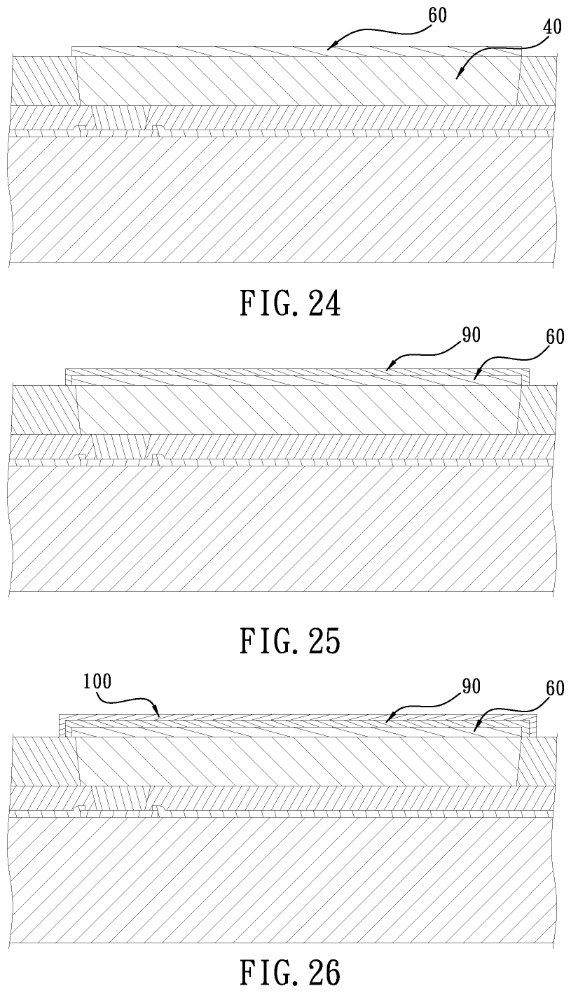

The chip 10 consists of a surface 11, at least one die pad 12 and at least one chip protection layer 13 which are arranged at the surface 11. The chip 10 is formed by cutting of a wafer 2, as shown in FIG. 8, FIG. 15, FIG. 22, and FIG. 28.

The first dielectric layer 20 is disposed on and covering a surface of the chip protection layer 13 of the chip 10 and provided with at least one first groove 21 by which the die pad 12 is exposed, as shown in FIG. 1 and FIG. 3.

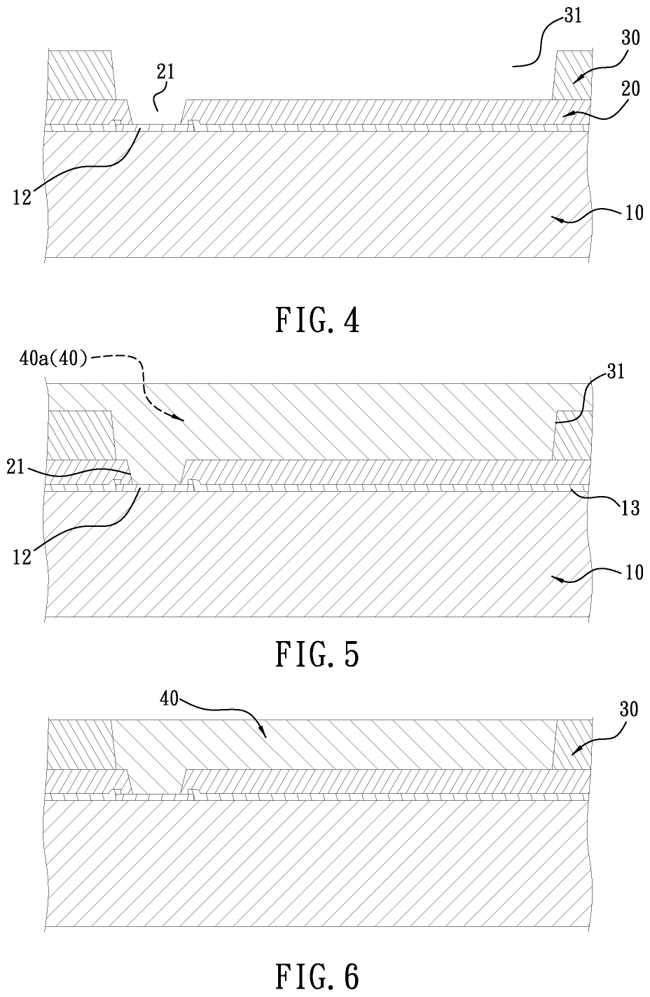

The second dielectric layer 30 is disposed on and covering a surface of the first dielectric layer 20 and is provided with at least one second groove 31 which is communicating with the first groove 21 of the first dielectric layer 20, as shown in FIG. 1 and FIG. 4.

The conductive circuit 40 is formed by highly concentrated silver paste or copper paste filled in the first groove 21 and the second groove 31 and the die pad 12 is allowed to be electrically connected with the conductive circuit 40, as shown in FIG. 1. The highly concentrated silver paste is composed of resin materials and silver while the amount of the silver in the highly concentrated silver paste is larger than the amount of the resin material in the highly concentrated silver paste. The highly concentrated copper paste is composed of resin materials and copper while a ratio of the copper to the highly concentrated copper paste is larger than a ratio of the resin material to the highly concentrated copper paste.

The highly concentrated silver paste or the highly concentrated copper which forms the conductive circuit 40 is nano silver paste or nano copper paste for increasing electrical conduction efficiency.

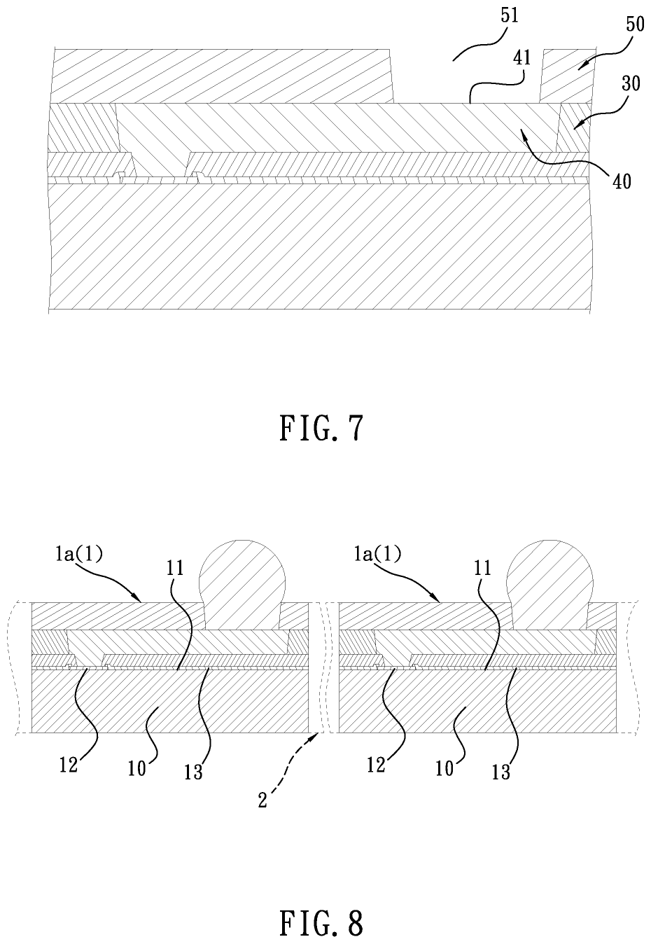

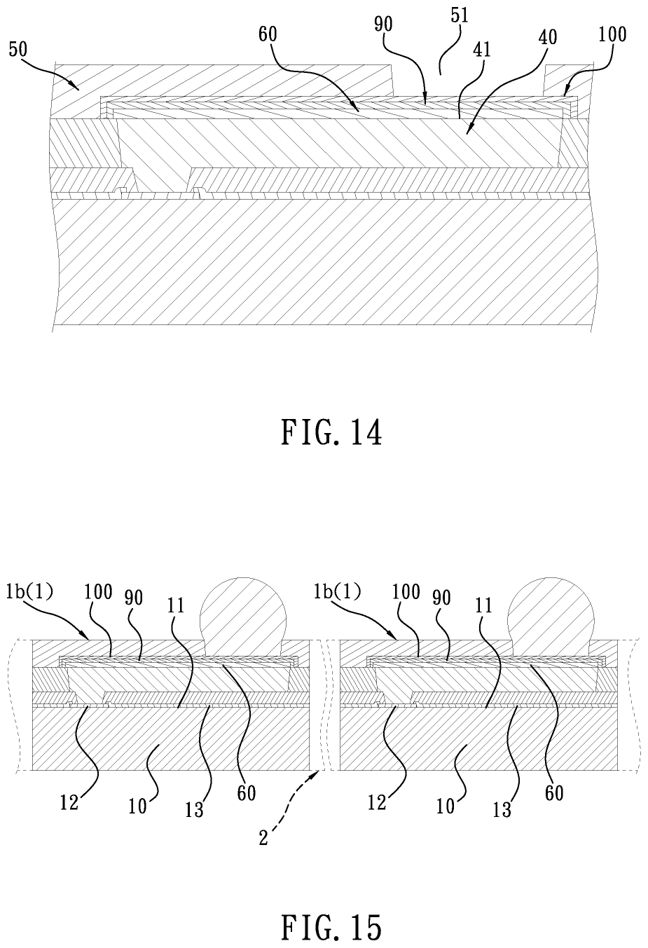

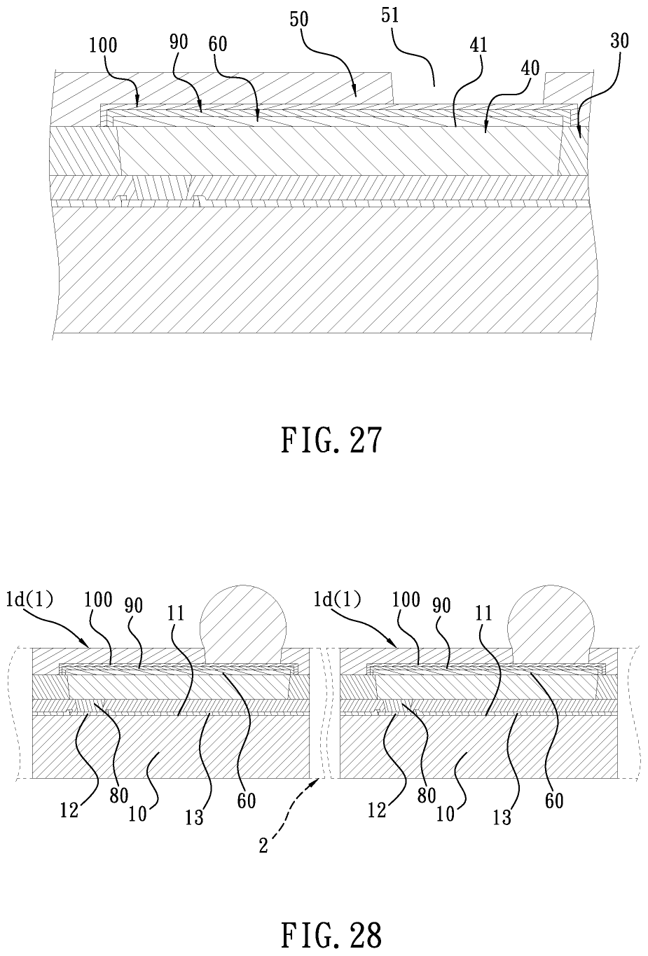

The third dielectric layer 50 which is covering both a surface of the second dielectric layer 30 and a surface of the conductive circuit 40 is provided with at least one opening 51 by which the conductive circuit 40 is exposed, as shown in FIG. 1 and FIG. 7. As shown in FIG. 1, FIG. 7, FIG. 14, FIG. 21, and FIG. 27, at least one bonding pad 41 is formed on the conductive circuit 40 at a position corresponding to the opening 51 for electrical connection to the outside.

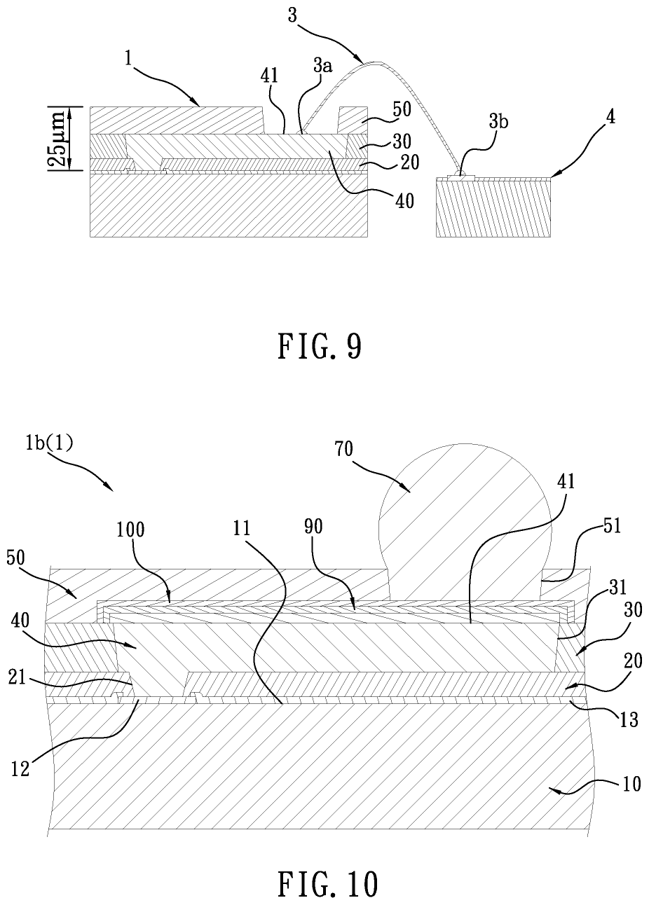

As shown in FIG. 9, a total thickness of a stacked body which is formed by the first dielectric layer 20, the second dielectric layer 30, the conductive circuit 40, and the third dielectric layer 50 stacked over each other and with enhanced overall structural strength is, but not limited to, 25 micrometers 1 m).

The chip package 1 of the present invention can be electrically connected with external electronic components by solder welding or wire bonding. While using the solder welding for electrical connection, at least one solder ball 70 is arranged at the opening 51 of the third dielectric layer of the chip package 1, as shown in FIG. 1, FIG. 10, FIG. 16, and FIG. 23. Thus the conductive circuit 40 is electrically connected to the external electronic components by the solder ball 70. When the wire bonding is used, a first bonding point 3a and a second bonding point 3b are respectively formed on the conductive circuit 40 in the opening 51 and an electronic component 4 by a bonding wire 3 so as to form electrical connection between the chip package 1 and the electronic component 4, as shown in FIG. 9.

Refer to FIG. 1-8, FIG. 15, FIG. 22, and FIG. 28, a method of manufacturing the chip package 1 according to the present invention includes the following steps.

Step S1: providing a chip 2 which is provided with a plurality of chips 10 arranged in an array, as shown in FIG. 8, FIG. 15, FIG. 22, and FIG. 28, and each of the chips 10 having a surface 11, at least one die pad 12 arranged at the surface 11, and at least one chip protection layer 13 disposed on the surface 11, as shown in FIG. 2.

Step S2: covering a surface of the chip protection layer 13 of the chip 10 with at least one first dielectric layer 20 on which at least one first groove 21 is formed and the die pad 12 is exposed by the first groove 21, as shown in FIG. 3.

Step S3: covering a surface of the first dielectric layer 20 with at least one second dielectric layer 30 on which at least one second groove 31 is formed and the second groove 31 is communicating with the first groove 21 of the first dielectric layer 20, as shown in FIG. 4.

Step S4: filling highly concentrated silver paste or copper paste into the first groove 21 and the second groove 31 to form a metal paste layer whose surface is at a higher level than a surface of the second dielectric layer 30, as shown in FIG. 5.

Step S5: grinding the metal paste layer 40a (as shown in FIG. 5) formed by the highly concentrated silver paste or copper paste and having the surface at a higher level than the surface of the second dielectric layer 30 until the surface of the second dielectric layer 30 is exposed and a surface of the highly concentrated silver paste or copper paste is flush with the surface of the second dielectric layer 30 to form at least one conductive circuit 40, as shown in FIG. 6. The die pad 12 is electrically connected with the conductive circuit 40, as shown in FIG. 1.

Step S6: covering a surface of the second dielectric layer 30 and a surface of the conductive circuit 40 with at least one third dielectric layer 50 which is provided with at least one opening 51 for allowing the conductive circuit 40 to be exposed, as shown in FIG. 1 and FIG. 7. At least one bonding pad 41 is formed on the conductive circuit 40 at the position corresponding to the opening 51 for electrical connection with external components, as shown in FIG. 7.

Refer to FIG. 1, FIG. 10, FIG. 16, and FIG. 23, the first embodiment (chip package 1a), a second embodiment (chip package 1b), a third embodiment (chip package 1c), and a fourth embodiment (chip package 1d) are provided. As shown in FIG. 1, the chip package 1(1a) of the first embodiment doesn't include a conductive bump 60 and a die-pad bump 80. Refer to FIG. 10, the chip package 1(1b) of the second embodiment is 20 provided with at least one conductive bump 60. Refer to FIG. 16, the chip package 1(1c) of the third embodiment is provided with at least one die-pad bump 80. Refer to FIG. 23, the chip package 1(1d) of the fourth embodiment is provided with at least one conductive bump 60 and at least one die-pad bump 80. As shown in FIG. 1, FIG. 10, FIG. 16, and FIG. 23, the structure or technical feature of the chip 10, the first dielectric layer 20, the second dielectric layer 30, the conductive circuit 40, and the third dielectric layer 50 in the first embodiment (chip package 1a), the second embodiment (chip package 1b), the third embodiment (chip package 1c), and the fourth embodiment (chip package 1d) is almost the same.

The conductive bump 60 is a bump formed by a nickel (Ni) layer and a gold (Au) layer, or a palladium (P) layer and a gold (Au) layer, or a combination of a nickel (Ni) layer, a palladium (P) layer, and a gold (Au) layer, but not limited. The cost is saved due to less amount of gold used. The die-pad bump 80 is a bump formed by a nickel (Ni) layer and a gold

(Au) layer, or a palladium (P) layer and a gold (Au) layer, or a combination of a nickel (Ni) layer, a palladium (P) layer, and a gold (Au) layer, but not limited. The cost is lowered due to less amount of gold used.

In the first embodiment shown in FIG. 1 and FIG. 8, the chip package 1a doesn't include the conductive bump 60 and the die-pad bump 80. Thus the die pad 12 of the chip 1 is electrically connected with external devices directly by the conductive circuit 40 and this is beneficial to improvement of electrical conduction efficiency of the product. There is no need to dispose the conductive bump 60 and the die-pad bump 80 on the chip package 1a so that the cost is saved due to simplified steps in a manufacturing process.

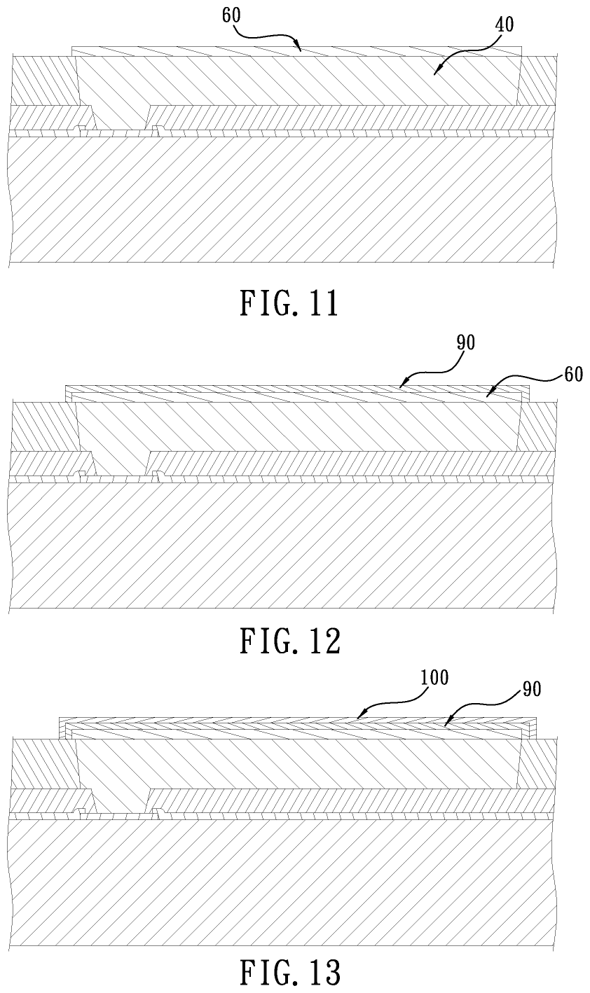

In the second embodiment shown in FIG. 10 and FIG. 15, the chip package 1b is provided with at least one conductive bump 60 electrically connected with and disposed over the conductive circuit 40 (as shown in FIG. 10, FIG. 11 and FIG. 14). As shown in FIG. 12, at least one first protective layer 90 is electrically connected with and arranged at the conductive bump 60 for protection of the conductive bump 60 and improvement of yield rate of the product. Refer to FIG. 13 and FIG. 14, at least one second protective layer 100 is electrically connected with and disposed over the first protective layer 90 for protecting the conductive bump 60 and improving yield rate of the product.

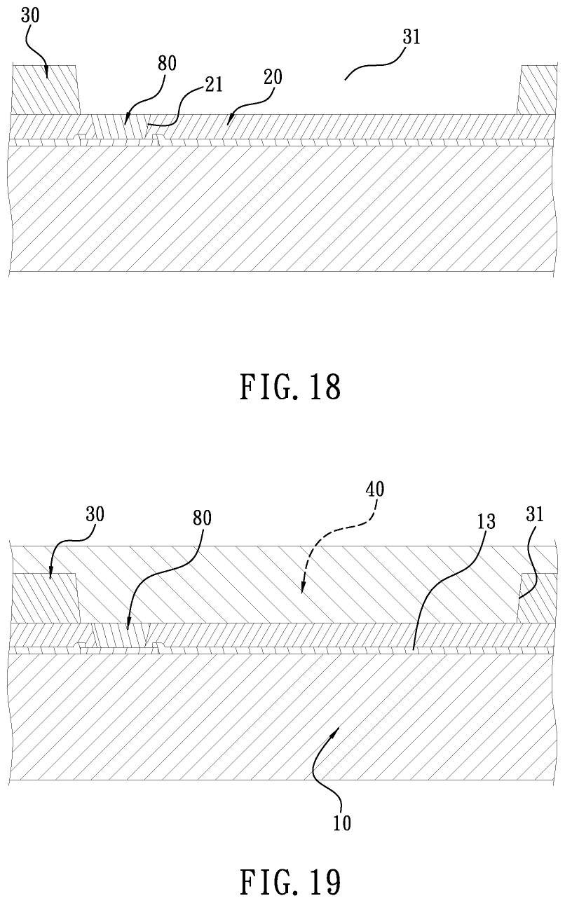

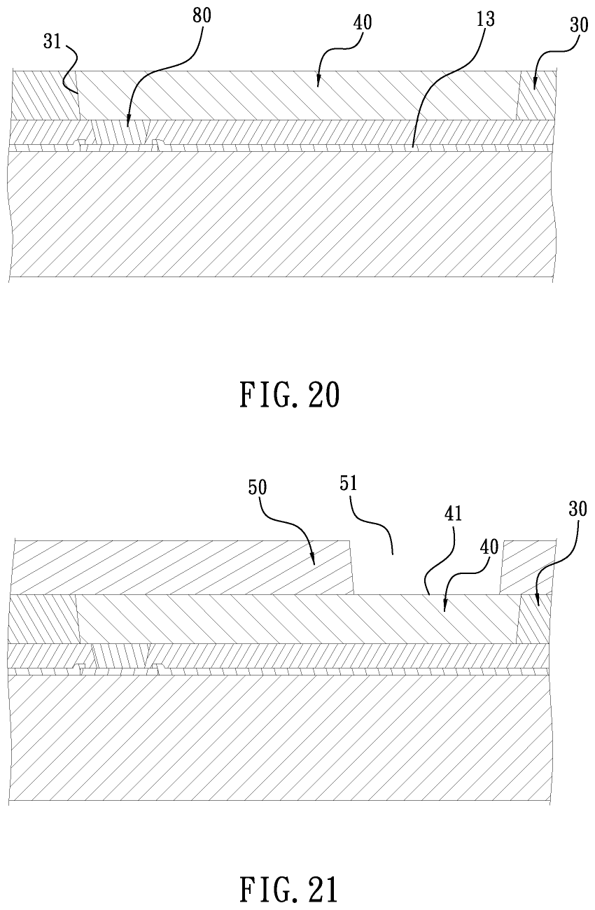

In the third embodiment shown in FIG. 16 and FIG. 22, the chip package 1c is provided with at least one die-pad bump 80 formed in the first groove 21 and electrically connected with and disposed over a surface of the die pad 12 (as shown in FIG. 16-18). Refer to FIG. 19 and FIG. 20, the conductive circuit 40 is in the second groove 31 and ground until a surface of the second dielectric layer 30 is exposed. Thus the one die-pad bump 80 is electrically connected with the conductive circuit 40.

In the third embodiment shown in FIG. 23 and FIG. 28, the chip package 1d is provided with at least one conductive bump 60 and at least one die-pad bump 80. The conductive bump 60 is disposed on and electrically connected with a surface of the conductive circuit 40 for protecting the conductive circuit 40 and improving yield rate of the product. The die-pad bump 80 is formed in the first groove 21, electrically connected with and arranged at a surface of the die pad 12, as shown in FIG. 26. The conductive circuit 40 is in the second groove 31 and ground until a surface of the second dielectric layer 30 is exposed. Thus the die-pad bump 80 is electrically connected with the conductive circuit 40, as shown in FIG. 23.

As shown in FIG. 25, the conductive bump 60 is further electrically connected with at least one protective layer 90 for protection of the conductive bump 60 and improvement of yield rate of the product. Refer to FIG. 26, the first protective layer 90 is further electrically connected with at least one second protective layer 100 for protecting the conductive bump and improving yield rate of the product.

1. A chip package comprising:
a chip having a surface, a at least one die pad disposed on the surface, and at least one chip protection layer arranged at the surface; wherein the chip is formed by cutting of a wafer;
at least one first dielectric layer which is covering a surface of the chip protection layer of the chip and provided with at least one first groove by which the die pad is exposed;
at least one second dielectric layer which is covering a surface of the first dielectric layer and is provided with at least one second groove which is communicating with the first groove of the first dielectric layer;
at least one conductive circuit which is formed by highly concentrated silver paste or copper paste filled in the first groove and the second groove and electrically connected with the die pad;
at least one third dielectric layer covering both a surface of the second dielectric layer and a surface of the conductive circuit and provided with at least one opening by which the conductive circuit is exposed; at least one bonding pad is formed on the conductive circuit and corresponding to the opening for electrical connection to the outside;
wherein a method of manufacturing the chip package comprising the steps of:
Step S1: providing a chip which is provided with a plurality of chips arranged in an array and each of the chips having a surface, at least one die pad arranged at the surface, and at least one chip protection layer disposed on the surface;
Step S2: covering a surface of the chip protection layer of the chip with at least one first dielectric layer on which at least one first groove is formed and the die pad is exposed by the first groove;
Step S3: covering a surface of the first dielectric layer with at least one second dielectric layer on which at least one second groove is formed and the second groove is communicating with the first groove of the first dielectric layer;
Step S4: filling highly concentrated silver paste or copper paste into the first groove and the second groove while a surface of the highly concentrated silver paste or copper paste is at a higher level than a surface of the second dielectric layer;
Step S5: grinding the highly concentrated silver paste or copper paste having the surface at the higher level than the surface of the second dielectric layer until the surface of the second dielectric layer is exposed and the surface of the highly concentrated silver paste or copper paste is flush with the surface of the second dielectric layer to form at least one conductive circuit; wherein the die pad is electrically connected with the conductive circuit; and
Step S6: covering the surface of the second dielectric layer and a surface of the conductive circuit with at least one third dielectric layer which is provided with at least one opening for allowing the conductive circuit to be exposed; wherein at least one bonding pad is formed on the conductive circuit and corresponding to the opening for external electrical connection.

2. The chip package as claimed in claim 1, wherein the surface of the conductive circuit is further electrically connected and provided with at least one conductive bump.

3. The chip package as claimed in claim 2, wherein the conductive bump is a bump formed by a nickel (Ni) layer and a gold (Au) layer, a bump formed by a palladium (P) layer and a gold (Au) layer, or a bump formed by a nickel (Ni) layer, a palladium (P) layer, and a gold (Au) layer.

4. The chip package as claimed in claim 2, wherein at least one first protective layer is electrically connected with and arranged over the conductive bump.

5. The chip package as claimed in claim 4, wherein at least one second protective layer is electrically connected with and disposed over the first protective layer.

6. The chip package as claimed in claim 1, wherein a total thickness of a combination of the first dielectric layer, the second dielectric layer, the conductive circuit, and the third dielectric layer stacked over each other is 25 micrometers (μm).

7. The chip package as claimed in claim 1, wherein highly concentrated silver paste or copper paste which forms the conductive circuit is nano silver paste or nano copper paste.

8. The chip package as claimed in claim 1, wherein at least one solder ball is arranged at the opening of the third dielectric layer so that the conductive circuit is electrically connected to the outside by the solder ball.

9. The chip package as claimed in claim 1, wherein a first bonding point and a second bonding point are respectively formed on the conductive circuit in the opening and an electronic component by a bonding wire used in wire bonding to form electrical connection between the chip package and the electronic component.

10. A chip package comprising:
a chip having a surface, a at least one die pad disposed on the surface, and at least one chip protection layer arranged at the surface; wherein the chip is formed by cutting of a wafer;
at least one first dielectric layer which is covering a surface of the chip protection layer of the chip and provided with at least one first groove by which the die pad is exposed;
at least one die-pad bump formed in the first groove, located on a surface of the die pad, and electrically connected with the die pad;
at least one second dielectric layer which is covering a surface of the first dielectric layer and is provided with at least one second groove which is communicating with the first groove of the first dielectric layer;
at least one conductive circuit which is formed by highly concentrated silver paste or copper paste filled in the first groove and the second groove and electrically connected with the die pad; and
at least one third dielectric layer covering both a surface of the second dielectric layer and a surface of the conductive circuit and provided with at least one opening by which the conductive circuit is exposed; at least one bonding pad is formed on the conductive circuit and corresponding to the opening for external electrical connection;
wherein a method of manufacturing the chip package comprising the steps of:
Step S1: providing a chip which is provided with a plurality of chips arranged in an array and each of the chips having a surface, at least one die pad arranged at the surface, and at least one chip protection layer disposed on the surface 11;
Step S2: covering a surface of the chip protection layer of the chip with at least one first dielectric layer on which at least one first groove is formed and the die pad is exposed by the first groove;
Step S3: forming at least one die-pad bump in the first groove while the die-pad bump is located on a surface of the die pad and electrically connected with the die pad;
Step S4: covering a surface of the first dielectric layer with at least one second dielectric layer on which at least one second groove is formed; the second groove is communicating with the first groove of the first dielectric layer;
Step S5: filling highly concentrated silver paste or copper paste into the first groove and the second groove while a level of the highly concentrated silver paste or copper paste is higher than a surface of the second dielectric layer;
Step S6: grinding the highly concentrated silver paste or copper paste with the level higher than the surface of the second dielectric layer so that the surface of the second dielectric layer is exposed and a surface of the highly concentrated silver paste or copper paste is flush with the surface of the second dielectric layer to form at least one conductive circuit; wherein the die-pad bump is electrically connected with the conductive circuit; and
Step S7: covering a surface of the second dielectric layer and a surface of the conductive circuit with at least one third dielectric layer which is provided with at least one opening for allowing the conductive circuit to be exposed; wherein at least one bonding pad is formed on the conductive circuit and corresponding to the opening for external electrical connection.

11. The chip package as claimed in claim 10, wherein the surface of the conductive circuit is provided with at least one conductive bump and the conductive bump is electrically connected with the conductive circuit.

12. The chip package as claimed in claim 11, wherein the conductive bump is a bump formed by a nickel (Ni) layer and a gold (Au) layer, or a bump formed by a palladium (P) layer and a gold (Au) layer, or a bump formed by a nickel (Ni) layer, a palladium (P) layer, and a gold (Au) layer.

13. The chip package as claimed in claim 11, wherein at least one first protective layer is electrically connected with and arranged over the conductive bump.

14. The chip package as claimed in claim 13, wherein at least one second protective layer is electrically connected with and disposed over the first protective layer.

15. The chip package as claimed in claim 10, wherein the die-pad bump is a bump formed by a nickel (Ni) layer and a gold (Au) layer, or a bump formed by a palladium (P) layer and a gold (Au) layer, or a bump formed by a nickel (Ni) layer, a palladium (P) layer, and a gold (Au) layer.

16. The chip package as claimed in claim 10, wherein a total thickness of a combination of the first dielectric layer, the second dielectric layer, the conductive circuit, and the third dielectric layer stacked over each other is 25 micrometers (μm).

17. The chip package as claimed in claim 10, wherein highly concentrated silver paste or copper paste which forms the conductive circuit is nano silver paste or nano copper paste.

18. The chip package as claimed in claim 10, wherein at least one solder ball is arranged at the opening of the third dielectric layer so that the conductive circuit is electrically connected to the outside by the solder ball.

19. The chip package as claimed in claim 10, wherein a first bonding point and a second bonding point are respectively formed on the conductive circuit in the opening and an electronic component by a bonding wire used in wire bonding to form electrical connection between the chip package and the electronic component.
